(19) United States
(12) Patent Application Publication
(10) Pub. No.: US 2005/0062113 A1
(43) Pub. Date: Mar. 24, 2005

(54) Semiconductor device with an insulating layer including deuterium and a manufacturing method thereof

(75) Inventor: Shinichi Watanabe, Kanagawa-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 10/802,810

(22) Filed: Mar. 18, 2004

(30) Foreign Application Priority Data
Sep. 19, 2003 (JP) 2003-328267

(51) Int. Cl. H01L 29/76

(52) U.S. Cl. 257/410

(57) ABSTRACT

A semiconductor device with an insulating layer including deuterium comprising: a semiconductor substrate; a gate insulating film including deuterium therein and formed on the semiconductor substrate; diffusion layers formed in the semiconductor substrate and located apart from each other to be adjacent to the gate insulating film; a gate electrode formed on the gate insulating film; a first insulating film including deuterium therein and formed on a side surface of the gate electrode; and a protective layer formed so as to cover the first insulating film.

### CROSS-REFERENCE TO RELATED APPLICATION

This application is based upon and claims the benefit of priority from the prior Japanese Patent Application No. 2003-328267 filed Sep. 19, 2003, the entire contents of which are incorporated herein by reference.

### BACKGROUND OF THE INVENTION

1. Field of the Invention

This present invention relates to a semiconductor device with an insulating layer including deuterium and a manufacturing method thereof.

2. Description of the Related Art

As a semiconductor memory device, for instance, a DRAM (Dynamic Random Access Memory) is down-sized and integrated, it is needed to form a smaller memory cell. In order to achieve that, a design rule, for instance, a length of a gate electrode of a transistor is shorter, thereby being down-sized. However, a capacity of a capacitor may be also smaller. Thereby it could cause a smaller capacity of the capacitor and a shorter retention time.

In order to prevent the retention time from being shorter, a leak current of the memory transistor could be controlled and reduced, other than a bigger size of the capacitor could be provided. The leak current of the memory transistor will occur at a junction. Specifically, it is conceivable that the leak current caused by occurrence of surface states at a junction region between a silicon layer and a silicon oxide layer could cause the retention time to be shorter. Conventionally, in order to prevent the surface states from occurring, dangling bonds at the surface region are forced to be terminated by hydrogen, thereby reducing density of the surface states at the junction. Specifically, a sinter step by using hydrogen gas is performed, and hydrogen is supplied into the surface between the silicon and the silicon oxide layer, thereby terminating the dangling bonds.

FIG. 8 shows a cross sectional view of a conventional semiconductor memory device. As shown in FIG. 8, a trench capacitor 202, an element isolating isolation region 203 (hereinafter, referred to a STI (Shallow Trench Isolation)) are formed in an upper surface of a semiconductor substrate 201. Diffusion layers 204 and 205 which are used as source and drain layers are formed in the upper surface of the semiconductor substrate 201 so as to be apart from each other. And one of the diffusion layers 204 and 205 is electrically connected the trench capacitor 202. Gate electrodes are formed on the STI region 203 and a channel region between the diffusion layers 204 and 205. And also, each of the gate electrodes is comprised of a poly crystalline silicon layer 211, a tungsten siliside layer 212, a cap silicon nitride layer 213, and a side wall insulating layer 221.

FIG. 9 shows a cross sectional view of the memory cell transistor in detail. A silicon oxide layer 241 is formed on the upper surface of the semiconductor substrate 201. A silicon oxide layer 242 is formed on side surfaces of the poly crystalline silicon layer 211 and the tungsten siliside layer 212.

However, the conventional memory cell device has some problems as below. A binding energy between the dangling bond and hydrogen is relatively low. Therefore, it will be easy for bound hydrogen at the bonding to be broken away from the bonding due to a thermal stress. After adding the thermal stress, it is known that a change of a retention characteristic may occur due to the break away of hydrogen from the bonding.

FIG. 10 schematically shows a cross sectional view indicating the boundary state between a silicon layer and a silicon oxide layer (not shown). As shown in FIG. 10, dangling bonds around the boundary between a silicon layer and a silicon oxide layer are made to be terminated by hydrogen. However, it will be easy for the bound hydrogen at the bonding to be broken away from the bonding due to the thermal stress caused by a current flow. As a result, even semiconductor memory devices qualified at product inspections may be inferior products, thereby making its productivity lowered.

And also, in the other conventional semiconductor device (Japanese laid open 2002-2299612), dangling bonds are made to be terminated by deuterium, instead of hydrogen. However, after a sinter step using hydrogen, the bound deuterium could be replaced with the hydrogen. As a result, it is easy for the replaced and bound hydrogen to be broken away from the bonding due to the thermal stress caused by the current flow. Thereby, data retention time of the conventional semiconductor device could be shorter.

### SUMMARY OF INVENTION

A first aspect of the present invention is providing a semiconductor device with an insulating layer including deuterium comprising: a semiconductor substrate; a gate insulating film including deuterium therein and formed on the semiconductor substrate; diffusion layers formed in the semiconductor substrate and located apart from each other to be adjacent to the gate insulating film; a gate electrode formed on the gate insulating film; a first insulating film including deuterium therein and formed on a side surface of the gate electrode; and a protective layer formed so as to cover the first insulating film.

A second aspect of the present invention is providing a semiconductor device with an insulating layer including deuterium comprising: a semiconductor substrate; a gate insulating film including deuterium therein and formed on the semiconductor substrate; diffusion layers formed in the semiconductor substrate and located apart from each other to be adjacent to the gate insulating film; a gate electrode formed on the gate insulating film; a protective layer formed so as to cover the gate insulating film and the gate electrode.

A third aspect of the present invention is providing a method for manufacturing a semiconductor device with an insulating layer including deuterium, comprising: forming a gate insulating film including deuterium therein on a semiconductor substrate; forming a gate electrode on the gate insulating film; forming a first insulating film which includes deuterium therein on a side surface of the gate electrode; forming diffusion layers in the semiconductor substrate to be adjacent to the gate insulating film; and forming a protective layer above the gate insulating film and the first insulating film.

### BRIEF DESCRIPTION OF THE DRAWINGS

FIG. 1 schematically shows a cross sectional view of a boundary between a silicon layer and a silicon oxide, to which deuterium is supplied, in a first embodiment of the present invention.

FIG. 2 shows a cross sectional view of a semiconductor memory device in the first embodiment of the present invention.

FIG. 3 shows a manufacturing step of the semiconductor memory device in the first embodiment of the present invention.

FIG. 4 shows a manufacturing step of the semiconductor memory device in the first embodiment of the present invention.

FIG. 5 shows a manufacturing step of the semiconductor memory device in the first embodiment of the present invention.

FIG. 6 shows a manufacturing step of the semiconductor memory device in the first embodiment of the present invention.

FIG. 7 shows a cross sectional view of a semiconductor memory device in the second embodiment of the present invention.

FIG. 8 shows a cross sectional view of a conventional semiconductor memory device.

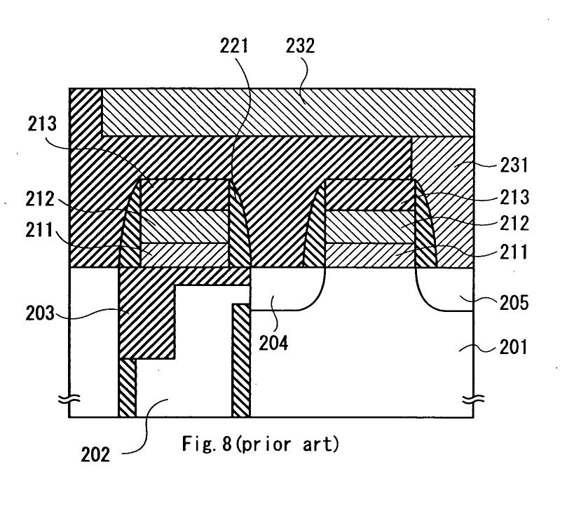

FIG. 9 shows a cross sectional view of a memory cell transistor located in the conventional semiconductor memory device.

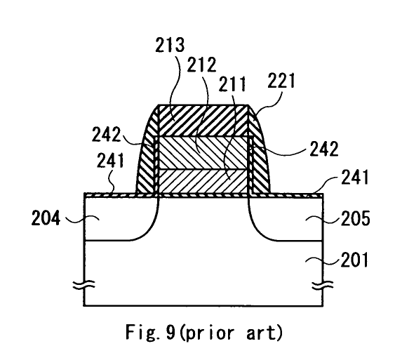

FIG. 10 schematically shows a cross sectional view of a boundary between a silicon layer and a silicon oxide, to which deuterium is supplied, in a conventional semiconductor memory device.

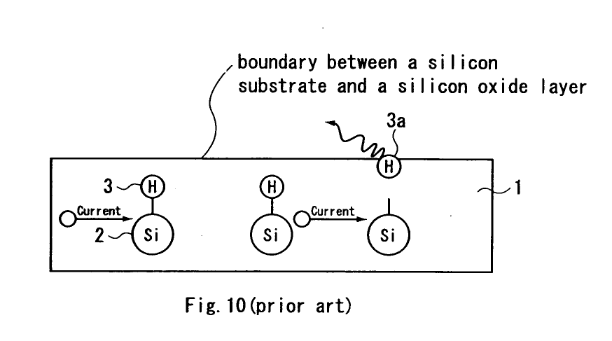

### DETAILED DESCRIPTION OF THE INVENTION

(First Embodiment)

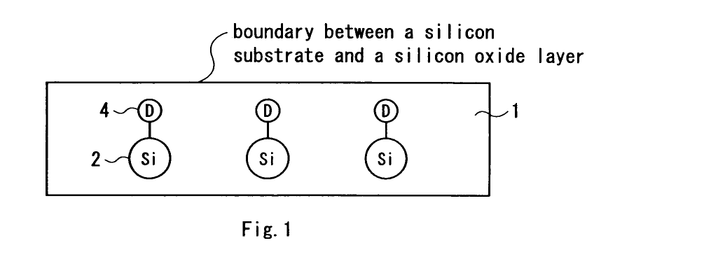

First of all, FIG. 1 schematically shows a boundary between a silicon layer and a silicon oxide layer (not shown). As stated above, conventionally, dangling bonds at the boundary between the silicon layer and the silicon oxide layer are made to be terminated by hydrogen. However, it will be easy for the hydrogen to be broken away from the bonding due to the thermal stress caused by the current flow. As a result, a shorter retention time and a lower productivity may be caused.

On the other hand, in a first embodiment of the present invention, dangling bonds at a boundary between a silicon layer and silicon oxide layer (not shown) are made to be terminated by deuterium. A bonding energy of deuterium is higher than that of the hydrogen. For this reason, it is more difficult for deuterium terminating the dangling bonds to be broken away from the bonding, thereby preventing a boundary level density caused by stresses of a thermal, an electric field, and so on from increasing.

A step of terminating the dangling bonds by deuterium is performed by a thermal step with deuterium gas, for instance, a step of forming an element isolation region, a step of forming a gate oxide of a transistor, a step of forming a side wall insulating layer, a CVD (Chemical Vapor Deposition) step, and so on. It should be noted that in case where a thermal step with hydrogen gas is performed after the step of terminating the dangling bonds by deuterium, the deuterium terminating the dangling bonds may be replaced with the hydrogen. Therefore, in order to prevent the deuterium from being broken away and replaced by the hydrogen that is going to be supplied after the step of the terminating the dangling bonds, it should be needed to protect a part of the boundary between the silicon layer and the silicon oxide layer.

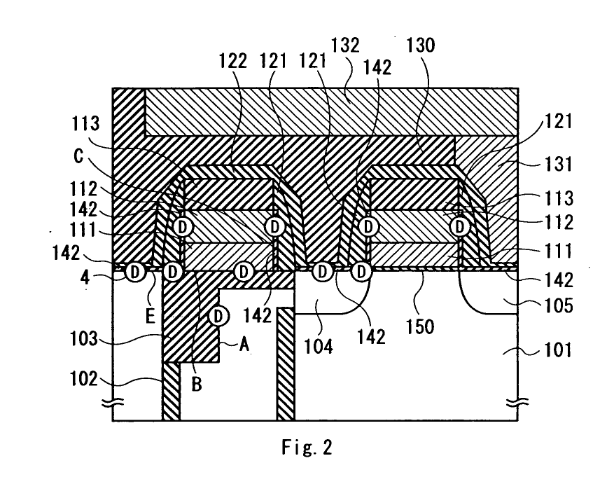

We will explain a semiconductor memory device of a first embodiment in the present invention with reference to drawings. FIG. 2 shows a cross sectional view of a semiconductor memory device of a first embodiment in the present invention. A trench capacitor 102 is formed in a semiconductor substrate 101. An element isolation insulating layer 103 is formed in an upper portion of the trench capacitor 102. Diffusion layers 104 and 105 which are used as source or drain layers are formed so as to electrically connect to the trench capacitor 102. A gate insulating film 105 is formed on the semiconductor substrate and between the diffusion layers 104 and 105. Gate electrodes which are comprised of a polycrystalline silicon layer 111 and a tungsten silicide layer 112 are formed on the gate insulating film 150 and the element isolation insulating layer 103. A silicon nitride layer 113 is formed on the gate electrodes in order to cap the gate electrodes.

Silicon oxide layers 142 are formed on side surfaces of the gate electrodes and on upper surfaces of the diffusion layers 104 and 105. Side wall insulating layers 121 which is made of a silicon nitride layer are formed on parts of the silicon oxide layers 142 and on side surfaces of the silicon nitride layer 113. A protective layer 122 which is made of one of an oxide aluminum and an insulating layer including nitrogen (for instance, SiN or SiON) is formed so as to cover the gate electrodes and the semiconductor substrate 101 entirely. An interlayer insulating layer 130 is formed on the protective layer 122. And also, a bit line 132 is formed on the interlayer insulating layer 130 and is electrically connected to the other one of the diffusion layers 104 and 105.

As shown in FIG. 2, it should be noted that deuterium terminates dangling bonds at a boundary A between the silicon substrate 101 and the element isolating insulation layer 103, a boundary B between the element isolating insulation layer 103 and the polycrystalline silicon layer 111, and a boundary C between the silicon oxide layer 142 and layers facing thereto, for instance, the tungsten silicide layer 112, the polycrystalline layer 111, the diffusion layers 104 and 105, and the semiconductor substrate 101.

In addition to that, it should be noted that a protective layer 122 which is made of the oxide aluminum or the insulating layer including nitrogen (SiN or SiON) is formed so as to cover oxide layers containing the deuterium in order to prevent hydrogen that is going to be supplied at following manufacturing steps from replacing the deuterium that is terminating the dangling bond.

As stated above, the protective layer 122 is formed entirely, but not limited to it. For example, the protective layer 122 may be formed so as to cover the gate insulating film 150, the silicon oxide layer 142, the diffusion layers 104 and 105, or the gate electrode.

And also, the side wall insulating layer 121 is formed so as to be physically contacted to the gate electrodes, but not limited to it. For example, the side wall insulating layer 121 is formed above the gate electrode.

And also, in the first embodiment, the trench capacitor formed in the semiconductor substrate is used, but not limited to this. For instance, it may be a stacked capacitor formed above the gate electrodes. And also, the STI is used as the element isolating isolation region, but not limited to this. For instance, it may be a LOCOS (Local Oxidation of Silicon).

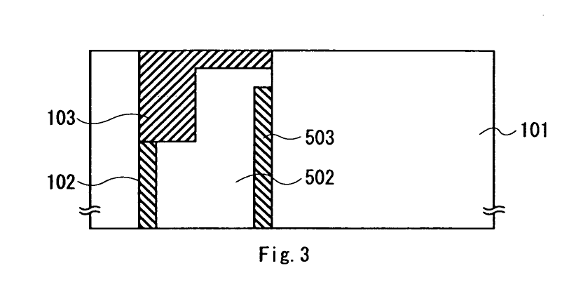

We will explain about a manufacturing method of the first embodiment in the present invention with reference to drawings. As shown in FIG. 3, a trench of 3000 to 3500 angstrom in depth is formed in the semiconductor substrate 101 by using a RIE (Reactive Ion Etching) method. And then, a thermal step, for instance, a wet oxidization step with 750 centigrade or more is performed, thereby forming a silicon oxide layer (not shown) on an inner surface of the trench. At the thermal step, atmosphere of deuterium is used. In a result, the oxide layer formed on the inner surface of the trench contains deuterium, thereby making the dangling bonds at a boundary between the silicon oxide layer and the inner surface of the trench terminated by the deuterium. An insulating layer 503, a polycrystalline silicon layer 502, and an element isolating insulation layer 103 are then formed in the trench, thereby forming the trench capacitor 102.

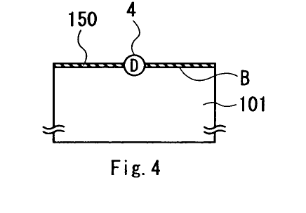

Hereinafter, for simplicity of an explanation, the trench capacitor 202 will be omitted. As shown in FIG. 4, a silicon insulating layer 150 is formed on the silicon substrate 101 by using a thermal step, for instance, a wet oxidization method with 750 centigrade or more. At the thermal step, atmosphere with deuterium is used, thereby making dangling bonds at a boundary B between the silicon substrate 101 and the silicon oxide layer 150 terminated by deuterium D.

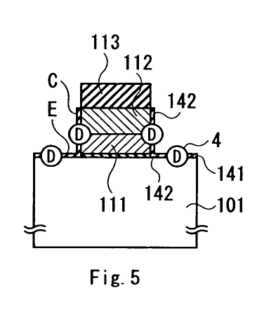

As shown in FIG. 5, a polycrystalline silicon layer 111 is formed on the gate insulating film 150 by using, for instance, a CVD (Chemical Vapor Deposition) method. A tungsten silicide layer 112 is then formed on the polycrystalline silicon layer 111 by using a spattering method. And then, a silicon nitride layer 113 is formed on the tungsten silicide layer 112. A photo resist layer patterned (not shown) is formed on the silicon nitride layer 113. Predetermined portions of the silicon nitride layer 113 are etched, thereby patterning the silicon nitride layer 113. After that, the photo resist layer patterned is removed. And then, by using a CVD method and using the patterned silicon nitride layer 113 as a mask, predetermined portions of the tungsten silicide layer 112 and the polycrystalline silicon layer 111 are removed, thereby forming the gate electrodes.

A silicon oxide layer 142 is formed on side surfaces of the tungsten silicide layer 112 and the polycrystalline silicon layer 111, and on the silicon substrate 101 by using a thermal step (for instance, a wet oxidization step with 750 centigrade or more) with an atmosphere with deuterium. At this thermal step, the silicon oxide layer 142 contains deuterium therein, thereby making the deuterium terminate dangling bonds at the boundaries C and E between the silicon oxide layer 142 and the gate electrode (the tungsten silicide layer 112 and the polycrystalline silicon layer 111) and between the silicon oxide layer 142 and the silicon substrate 101, respectively.

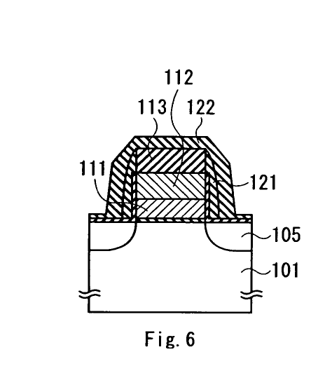

As shown in FIG. 6, the diffusion layers 104 and 105 are formed in the semiconductor substrate 101 by using an ion implantation method and using the gate electrode as a mask. The side wall insulating layers 121 that are made of, for instance, a silicon nitride are formed on the silicon oxide layer 112 and the silicon nitride layer 113 by using a RIE (Reactive Ion Etching) method. After that, if needed, impurities may be injected in the semiconductor substrate 101 in order to form second diffusion layers (not shown).

The protective layer 122 with, for instance, 200 angstrom in thickness is formed so as to cover the side wall insulating layers 121, the silicon nitride layer 113, and the semiconductor substrate 101. The protective layer 122 is made of, for instance, the oxide aluminum or the insulating layer including nitrogen (SiN or SiON).

It should be noted that a protective layer 122 which is made one of the oxide aluminum and the insulating layer including nitrogen (SiN or SiON) is formed so as to cover oxide layers containing the deuterium in order to prevent hydrogen that is going to be supplied at following manufacturing steps from replacing the deuterium that is terminating the dangling bond.

And also, it should be noted that a protective layer 122 is made one of the oxide aluminum and the insulating layer including nitrogen (SiN or SiON), but it is not limited to those. Material other than the oxide aluminum and the insulating layer including nitrogen (SiN or SiON) may be used.

In addition to that, it should be noted that the protective layer 122 is formed entirely, but not limited to it. For example, the protective layer 122 may be formed so as to cover the gate insulating film 150, the silicon oxide layer 142, the diffusion layers 104 and 105, or the gate electrode, or to cover some of them.

As stated above, at the forming step of the silicon oxide layer 142 in the first embodiment of the present invention, the silicon oxide layer 142 that is including deuterium therein is formed by using a CVD method with the atmosphere of deuterium, thereby making the dangling bonds at the boundaries between the silicon layer and the silicon oxide layer terminated by the deuterium. After that, the protective layer is formed so as to cover the oxide layers containing the deuterium in order to prevent hydrogen that is going to be supplied at following manufacturing steps from replacing the deuterium that is terminating the dangling bond.

(Second Embodiment)

We will explain a semiconductor memory device of a second embodiment in the present invention with reference to drawing. In the first embodiment of the present invention, the protective layer 152 is formed so as to cover entirely, after the gate electrode of the transistor is formed. However, in the semiconductor memory device in the second embodiment of the present invention, a protective layer 152 is formed after a formation of a silicon oxide layer containing deuterium on a gate electrode, and before a formation of a side wall insulating layer.

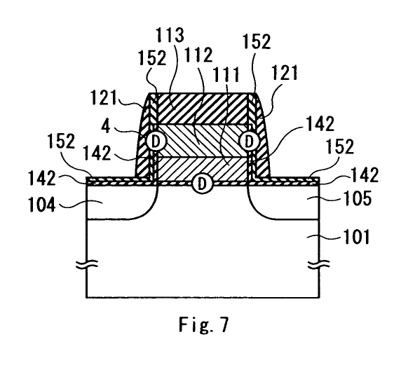

FIG. 7 shows a cross sectional view of a memory cell transistor formed in the semiconductor memory device in the second embodiment in the present invention. As shown in FIG. 7, deuterium is introduced into a silicon oxide layer 142 when the silicon oxide layer 142 is formed on an upper surface of a semiconductor substrate 101 and on side surfaces of a poly crystalline silicon layer 111 and a tungsten silicide layer 112, thereby making dangling bonds in silicon layers (the semiconductor substrate 101, the poly crystalline silicon layer 111, and the tungsten silicide layer 112) terminated by the deuterium.

A protective layer 152 that is made of one of an oxide aluminum and an insulating layer including nitrogen (for instance, SiN or SiON) is formed so as to cover the silicon oxide layer 142, the silicon nitride layer 113, and the silicon substrate 101. A side wall insulating layer 121 is then formed on the protective layer 152.

In the second embodiment in the present invention, the protective layer 152 is formed so as to cover the silicon oxide layer 142, thereby preventing hydrogen from replacing deuterium that is introduced into the silicon oxide layer 142 and terminates the dangling bonds.

Hereinafter, we will explain manufacturing steps of the semiconductor memory device of the second embodiment in the present invention with reference to drawings. And also, FIGS. 3 to 5 in the first embodiment of the present invention are common to manufacturing steps of the second embodiment of the present invention. Therefore, for simplicity of an explanation, we will omit some explanations of those.

As shown in FIG. 5, similarly to the first embodiment of in the present invention, a silicon oxide layer 142 is formed on an upper surface of the silicon substrate 101 and on side surfaces of the polycrystalline silicon layer 111 and the tungsten silicide layer 112, by using a thermal step, for instance, a wet oxidization step with 750 centigrade or more.

At the thermal step, the silicon oxide layer 142 is formed by using an atmosphere with deuterium, thereby being able to include deuterium in the silicon oxide layer 142. In a result, the deuterium can terminate the dangling bonds at the boundary C between the silicon oxide layer 142 and a gate electrode (the polycrystalline silicon layer 111 and the tungsten silicide 112), and the boundary E between the silicon oxide layer 142 and the silicon substrate 101.

After that, impurities are injected into the semiconductor substrate 101 by using an ion implantation method and using the silicon nitride layer 113 and the gate electrode as a mask, thereby forming diffusion layers 104 and 105. And then, a protective layer 152 that is made of one of an oxide aluminum and an insulating layer including nitrogen (for instance, SiN or SiON) is formed so as to cover the side surfaces of the silicon oxide layer 142 and the silicon nitride layer 113.

A side wall insulating layer 121 that is made of, for instance, a silicon nitride layer, is then formed on the protective layer 152 by using a CVD method and a RIE method.

It should be noted that a protective layer 152 made of one of the oxide aluminum and the insulating layer including nitrogen (SiN or SiON) is formed so as to cover oxide layers containing the deuterium in order to prevent hydrogen that is going to be supplied at following manufacturing steps from replacing the deuterium that is terminating the dangling bond.

And also, it should be noted that a protective layer 152 is made one of the oxide aluminum and the insulating layer including nitrogen (SiN or SiON), but it is not limited to those. Material other than the oxide aluminum and the insulating layer including nitrogen (SiN or SiON) may be used.

In addition to that, it should be noted that the protective layer 152 is formed entirely, but not limited to it. For example, the protective layer 152 may be formed so as to cover the gate insulating film, the silicon oxide layer 142, the diffusion layers 104, 105, or the gate electrode, or to cover some of them.

As stated above, at the forming step of the silicon oxide layer 142 in the second embodiment of the present invention, the silicon oxide layer 142 that includes deuterium therein is formed, thereby making the dangling bonds at the boundaries between the silicon layer and the silicon oxide layer terminated by the deuterium. After that, the protective layer 152 is formed so as to cover the oxide layers containing the deuterium in order to prevent hydrogen that is going to be supplied at following manufacturing steps from replacing the deuterium that is terminating the dangling bond.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended and their equivalents.

1. A semiconductor device with an insulating layer including deuterium comprising:
a semiconductor substrate;
a gate insulating film including deuterium therein and formed on the semiconductor substrate;
diffusion layers formed in the semiconductor substrate and located apart from each other to be adjacent to the gate insulating film;
a gate electrode formed on the gate insulating film;
a first insulating film including deuterium therein and formed on a side surface of the gate electrode; and
a protective layer formed so as to cover the first insulating film.

2. The semiconductor device with an insulating layer including deuterium according to claim 1, the protective layer is formed so as to cover the first insulating film and the gate insulating film.

3. The semiconductor device with an insulating layer including deuterium according to claim 1, further comprising:
a second insulating film including deuterium therein and formed on an inner surface of a trench which is formed in the semiconductor substrate; and
an element isolation insulating layer formed in the trench and on the second insulating layer.

4. The semiconductor device with an insulating layer including deuterium according to claim 1, further comprising a capacitor electrically connected to one of the diffusion layers.

5. The semiconductor device with an insulating layer including deuterium according to claim 1, the protective layer is one of an insulating layer including nitrogen and an oxide aluminum layer.

6. The semiconductor device with an insulating layer including deuterium according to claim 1, a third insulating film is formed on the gate electrode.

7. The semiconductor device with an insulating layer including deuterium according to claim 1, further comprising a side wall insulating film formed around the side surface of the gate electrode.

8. The semiconductor device with an insulating layer including deuterium according to claim 1, the first insulating film extends on the one of the diffusion layers.

9. A semiconductor device with an insulating layer including deuterium comprising:
a semiconductor substrate;
a gate insulating film including deuterium therein and formed on the semiconductor substrate;
diffusion layers formed in the semiconductor substrate and located apart from each other to be adjacent to the gate insulating film;
a gate electrode formed on the gate insulating film;
a protective layer formed so as to cover the gate insulating film and the gate electrode.

10. The semiconductor device with an insulating layer including deuterium according to claim 8, further comprising; a first insulating film including deuterium therein and formed on a side surface of the gate electrode.

11. The semiconductor device with an insulating layer including deuterium according to claim 10, the protective layer is formed so as to cover the first insulating film and the gate insulating film.

12. The semiconductor device with an insulating layer including deuterium according to claim 8, further comprising:
a second insulating film including deuterium therein and formed on an inner surface of a trench which is formed in the semiconductor substrate; and
an element isolation insulating layer formed in the trench and on the second insulating layer.

13. The semiconductor device with an insulating layer including deuterium according to claim 8, further comprising a capacitor electrically connected to one of the diffusion layers.

14. The semiconductor device with an insulating layer including deuterium according to claim 8, the protective layer is one of an insulating layer including nitrogen and an oxide aluminum layer.

15. The semiconductor device with an insulating layer including deuterium according to claim 8, a third insulating film is formed on the gate electrode.

16. The semiconductor device with an insulating layer including deuterium according to claim 8, further comprising a side wall insulating film formed around the side surface of the gate electrode.

17. The semiconductor device with an insulating layer including deuterium according to claim 8, the first insulating film extends on the one of the diffusion layers.

18. A method for manufacturing a semiconductor device with an insulating layer including deuterium, comprising:
forming a gate insulating film including deuterium therein on a semiconductor substrate;
forming a gate electrode on the gate insulating film;
forming a first insulating film which includes deuterium therein on a side surface of the gate electrode;
forming diffusion layers in the semiconductor substrate to be adjacent to the gate insulating film; and
forming a protective layer above the gate insulating film and the first insulating film.

19. The method for manufacturing a semiconductor device with an insulating layer including deuterium according to claim 18, further comprising:
forming a second insulating film including deuterium therein on an inner surface of a trench which is formed in the semiconductor substrate; and
forming an element isolation insulating layer in the trench and on the second insulating layer.

20. The method for manufacturing a semiconductor device with an insulating layer including deuterium according to claim 18, further comprising: further comprising: forming a capacitor electrically connected to one of the diffusion layers.

21. The method for manufacturing a semiconductor device with an insulating layer including deuterium according to claim 18, further comprising: forming a third insulating film on the gate electrode.

22. The method for manufacturing a semiconductor device with an insulating layer including deuterium according to claim 18, further comprising: forming a side wall insulating film around the side surface of the gate electrode.

23. The method for manufacturing a semiconductor device with an insulating layer including deuterium according to claim 18, the first insulating film extends on the one of the diffusion layers.
